(19) United States
(12) Patent Application Publication
(10) Pub. No.: US 2016/0360639 A1
(43) Pub. Date: Dec. 8, 2016

(54) DYNAMIC HEAT CONDUCTION SYSTEM

(71) Applicant: ADVANTECH CO., LTD., Taipei City (TW)

(72) Inventor: Chi-Hung HSIEH, Taipei City (TW)

(21) Appl. No.: 14/733,136

(22) Filed: Jun. 8, 2015

(51) Int. Cl. H05K 7/20

(52) U.S. Cl. CPC H05K 7/2039

(57) ABSTRACT

This invention provides a dynamic heat conduction system comprising a base, a resilient unit, a heat conduction block, and at least one securing unit. The base accommodates the resilient unit and the heat conduction block and the at least one securing unit secures at least a portion of the base and the resilient unit within the base. The heat conduction block comprises a heat conduction surface for forming a contact with an electronic device and accomplishes preferably efficient heat conduction by conducting the heat produced by the electronic device through the heat conduction surface, the heat conduction block, and a side surface of the heat conduction block to the base. Still, this invention provides a dynamic heat conduction system comprising a heat conduction board for accommodating a plurality of heat conduction blocks and a plurality of bases for forming a preferable heat conduction path with a plurality of electronic devices having different shapes or sizes.

### BACKGROUND OF THE INVENTION

Field of the Invention

This application relates to a dynamic heat conduction system. More particularly, this application relates to a dynamic heat conduction system applied to computer apparatus.

Description of the Prior Art

In computer apparatus, it generally used a heat conduction device with a heat conduction block to maintain the operation at a suitable temperature. The heat energy can be rapidly transferred from the electronic component to the heat conduction device by making the heat conduction block be closely contact to the electronic component that produced mass of heat.

For making the heat conduction block of the heat conduction device be closely contacted to the processor, one traditional method is disposing a thermal pad in the gap between the heat conduction block and the processor. The thermal pad produces an amount of deformation when the heat conduction block contacts to the processor so that the thermal pad closely contacts to the heat conduction block and the processor simultaneously. However, such a thermal pad generally has a high thermal resistance and the heat conduction device cannot adapt to different heights of electronic components while the thickness of the thermal pad is decreased as low as possible. Therefore, traditionally, people have to design different heat conduction devices for a variety of electronic components of different heights, which leads to a high cost. In addition, such a thermal pad has no buffering capacity that it easily causes damages to the electronic components when being subject to an external force or vibration.

Please refer to the heat conduction structure shown in FIG. 1 (Taiwan Utility Patent No. M451797) which stands for another traditional method for heat conduction block, which discloses a heat conduction block 3 having downward displacement to exert force to a connecting portion 21 of the heat conduction pipe 2 and the resilient positioning plate 4 when the electronic components and the heat conduction blocks of the circuit board (Not shown) contact to each other. The heat conduction block 3 can closely contact to an electronic component in one side and the heat conduction pipe 2 in other side simultaneously. The heat conduction block and the heat conduction pipe are secured with spring screws to complete a heat conduction structure with low thermal resistance. However, such a traditional method for heat conduction block has the following disadvantages: the distortion of heat pipes may cause heat pipes failure; the cost of heat pipes and spring screws is higher; it is difficult to assemble the electronic components in different height; it is difficult to maintain the heat conduction blocks and the electronic components contacting closely; and the heat conduction structure has no buffering capacity so that it is easy to cause damage to the electronic components in the vibration environment.

In addition, for the requirement of simultaneously processing heat conduction of a plurality of electronic components, the heat conduction device of the prior art is providing a corresponding heat conduction device for each electronic components. Therefore, the heat conduction block of the heat conduction device of the prior art obviously has inconveniences and defects which can be improved.

### SUMMARY OF THE INVENTION

In view of the problems of the traditional heat conduction blocks that described above, the present invention can avoid the damage of the heat conduction units and the electronic components caused by an external force when they are assembled, can keep the heat conduction units and the electronic components contacting closely at the same time, and can thus simplifying the process of a plurality of the electronic components which provided a plurality of the heat conduction units.

In view of the purpose of the present invention, a dynamic heat conduction system is provided. The dynamic heat conduction system comprises a base, a heat conduction block, a resilient unit and at least one securing unit. The base has a base surface and an inner side wall which defines at least two base securing holes having a base securing hole length along the direction of a normal line to the base surface. The heat conduction block comprises a heat conduction side wall and a heat conduction surface, the heat conduction side wall being opposite to the inner side wall of the base and a gap is defined between the heat conduction side wall and the inner side wall of the base. The heat conduction side wall comprises at least two heat conduction block securing holes at positions respectively corresponding to those of the base securing holes, the heat conduction block securing holes have a heat conduction block securing hole length along the direction of a normal line to the base surface of the base. The resilient unit has one end being disposed on the base surface of the base and the other end being opposite to the base surface of the base and being engaged with the heat conduction block, so that the heat conduction block is disposed in the base and the heat conduction surface remains outside the base. At least one securing unit has at least one portion being secured to the heat conduction block securing holes respectively and at least another one of the other portions being disposed in the base securing holes respectively, the securing unit has a securing unit width along the direction of a normal line to the base surface of the base. The base securing hole length is greater than the securing unit width and the securing unit width is greater than or equal to the heat conduction block securing hole length, so that the heat conduction block is movable in the direction of a normal line to the heat conduction surface and at least one portion thereof is restricted within the base.

Optionally, the dynamic heat conduction system comprises a heat conduction fluid disposed in the gap between the heat conduction side wall and the inner side wall of the base. Further, the heat conduction block has at least one groove on the heat conduction side wall for accommodating the heat conduction fluid.

Still, the dynamic heat conduction system comprises a hole penetrating the heat conduction block and forming the at least two heat conduction block securing holes on the heat conduction side wall.

In view of the purpose of the present invention, another dynamic heat conduction system is provided. The dynamic heat conduction system comprises a heat conduction board, a plurality of bases, a plurality of heat conduction blocks, a plurality of resilient units and a plurality of securing units. The heat conduction board covers a plurality of electronic components. The plurality of bases are disposed respectively on the heat conduction board at positions corresponding to the electronic components and respectively comprise a base surface and an inner side wall which defines at least two base securing holes having a base securing hole length along the direction of a normal line to the base surface. The plurality of heat conduction blocks are disposed respectively in the bases and respectively comprise a heat conduction side wall and a heat conduction surface, the heat conduction side walls respectively are opposite to the inner side wall of the bases and between the heat conduction side walls and the inner side wall of the bases respectively comprise a gap. The heat conduction side comprises at least two heat conduction block securing holes at positions respectively corresponding to those of the base securing holes, the heat conduction block securing holes respectively have a heat conduction block securing hole length along the direction of a normal line to the base surface of the bases. The plurality of resilient units are disposed respectively in the bases and respectively have one end being disposed on the base surface of the bases and the other end respectively being opposite to the base surface of the bases and are engaged with the heat conduction blocks, so that the heat conduction blocks are disposed respectively in the bases and the heat conduction surfaces remain outside the bases. The plurality of securing units are disposed respectively in the bases, respectively have at least one portion being secured to the heat conduction block securing holes and at least another portion being disposed in the base securing holes, and respectively have a securing unit width along the direction of a normal line to the base surface of the bases respectively. The base securing holes length are greater respectively than the securing units width and the securing units width are greater respectively than or equal to the heat conduction block securing holes length so that the heat conduction blocks are movable in the direction of a normal line to the heat conduction surface respectively and at least one portion thereof is restricted within the bases.

Optionally, the dynamic heat conduction system comprises a heat conduction fluid disposed in the gap between the heat conduction side wall and the inner side wall of the base. Further optionally, the plurality of heat conduction blocks have at least one groove on the heat conduction side walls for accommodating the heat conduction fluid.

Still, the plurality of heat conduction blocks have a hole penetrating the heat conduction blocks and forming the at least two heat conduction block securing holes on the heat conduction side wall.

Further, for corresponding to the heights of the plurality of electronic components, the plurality of bases have different heights of bases respectively, the plurality of heat conduction blocks have different heights of heat conduction blocks respectively or the plurality of resilient units have different heights of unit or different resilient coefficients respectively.

Further, for corresponding to a contact surface area of the plurality of electronic components, the plurality of heat conduction blocks have different heat conduction surface areas respectively or the plurality of resilient units have different resilient unit areas respectively.

Further, the plurality of bases can be secured on the heat conduction boards with a post processing nickel and the heat conduction board. The bases can also be secured on the heat conduction boards with screws.

According to the dynamic heat conduction system of the present invention, a buffering effect can be provided to avoid causing damage of the electronic components and the heat conduction system by external force and keeping the heat conduction system and the electronic components be contacted closely to achieve better heat conduction effect. In addition, according to the dynamic heat conduction system of the present invention, the heat conduction blocks can be provided to the plurality of electronic components respectively to achieve contacting closely and better heat conduction effect. The assembly process of the heat conduction unit and the plurality of electronic components can be simplified.

### BRIEF DESCRIPTION OF THE DRAWINGS

FIG. 1 is a heat conduction structure of the prior art.

FIG. 2 is an exploded view of an exemplary embodiment according to the dynamic heat conduction system of the present invention.

FIG. 3 is a top view of the embodiment shown in FIG. 2.

FIG. 4 is a sectional view drawn along Line A-A as shown in FIG. 3.

FIG. 5 is a top view of another embodiment according to the dynamic heat conduction system of the present invention.

FIG. 6 is a sectional view drawn along Line B-B as shown in FIG. 5.

FIG. 7 is a perspective view of another embodiment according to the dynamic heat conduction system of the present invention.

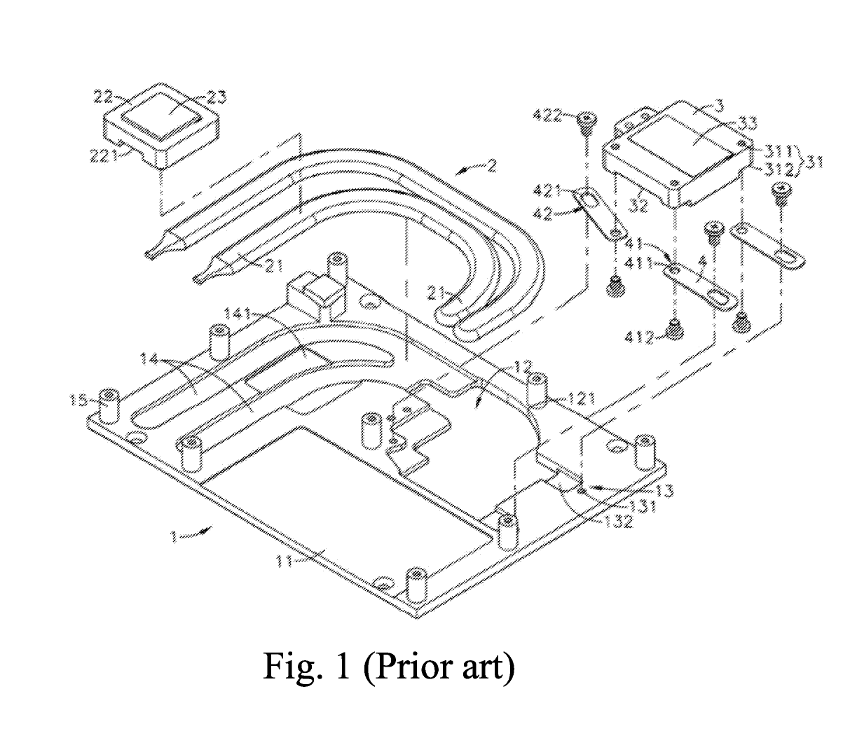

### DETAILED DESCRIPTION OF THE PREFERRED EMBODIMENTS

The following text is described by exemplary embodiments of the present invention and with reference to the drawings.

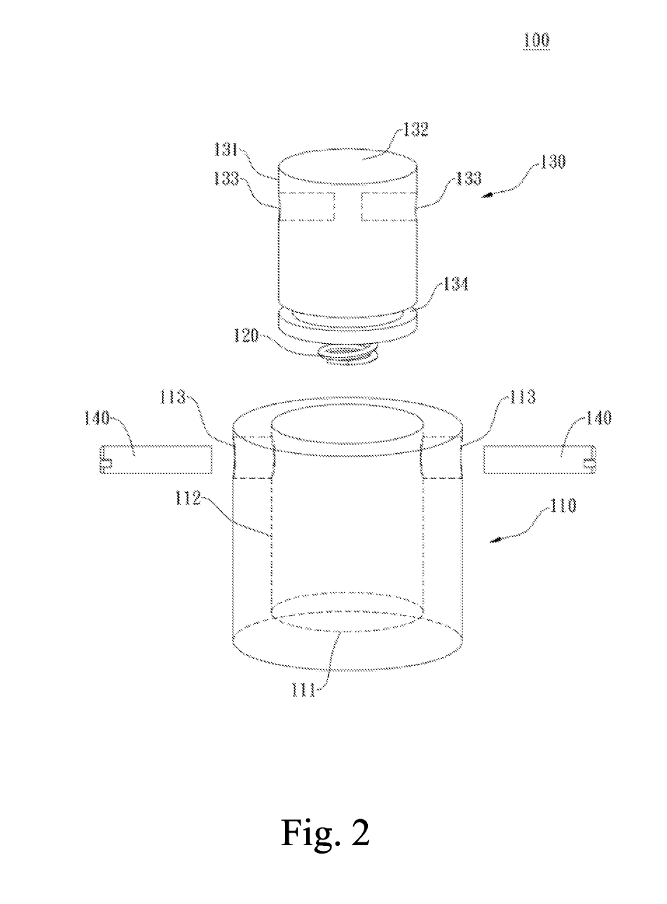

Please refer to FIG. 2, which is an exploded view of a dynamic heat conduction system 100 according to the present invention. A base 110, a resilient unit 120, a heat conduction block 130 and structures of securing units 140 are depicted. The base 110 comprises a base surface 111, an inner side wall 112 and base securing holes 113 on the inner side wall 112. One end of the resilient unit 120 is engaged with the base surface 111 of the base 110 and the other end of the resilient unit 120 is engaged with the heat conduction block 130. The heat conduction block 130 comprises a heat conduction side wall 131, a heat conduction surface 132, heat conduction block securing holes 133 and a groove 134.

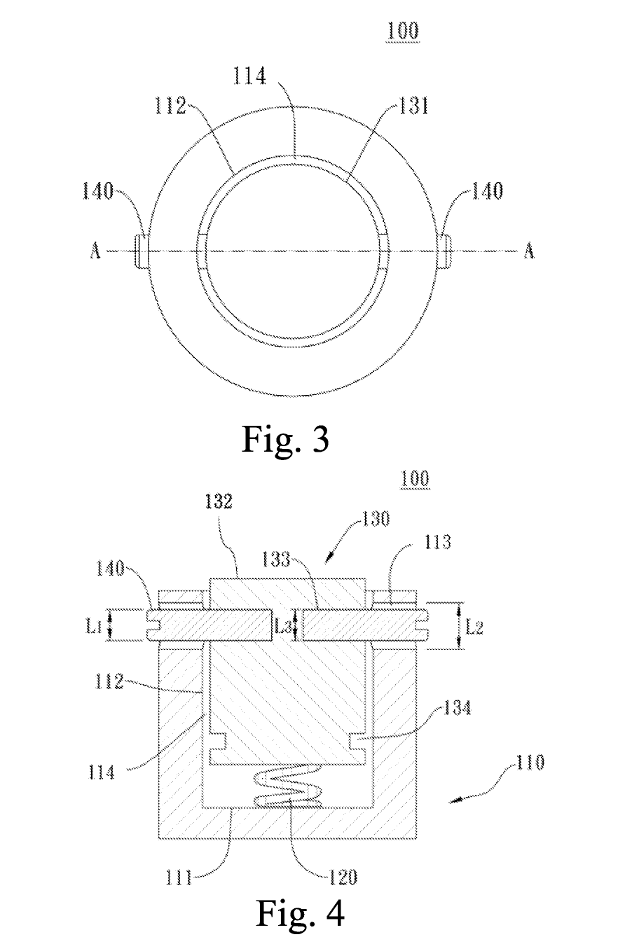

Please refer to FIG. 3, which is a top view of the dynamic heat conduction system 100 according to the present invention. The inner side wall 112 of the base 110 is opposite to the heat conduction side wall 131 of the heat conduction block 130 and a gap 114 is defined between the inner side wall 112 and the heat conduction side wall 131. Although the dynamic heat conduction system 100 of the embodiment is circular in the top view, the heat conduction block and base of dynamic heat conduction system of the present invention in a top view can also be elliptical, rectangular, etc. or have different size of heat conduction surface areas or base shedding surface areas so as to adapt to different shapes or areas of the electronic components. Preferably, the resilient unit of the dynamic heat conduction system of the present invention can also has a different resilient unit area in the direction of a normal line to the heat conduction surface to fit using different shapes or areas of the electronic components.

Please refer to FIG. 4, which is a sectional view drawn along line A-A shown in FIG. 3. A link relation of the various components after assembled in the dynamic heat conduction system 100 is depicted. One portion of the securing units 140 are secured to the heat conduction block securing holes 133, another portion of the securing units 140 are disposed in the base securing holes 113 and the securing units 140 have a securing unit width L1 along the direction of a normal line to the base surface 111. The base securing holes 113 have a base securing hole length L2 along the direction of a normal line to the base surface 111. The heat conduction block securing holes 133 have a heat conduction block securing hole length L3 along the direction of a normal line to the base surface 111. The condition of L2>L1≧L3 must be satisfied, so that at least one portion of the heat conduction block 130 is restricted within the base 110 by the securing unit 140 and the base securing holes 113 when the securing units 140 and the heat conduction block 130 are movable in the direction of a normal line to the base surface 111.

The heat conduction surface 132 of the heat conduction block 130 can be closely contacted to a electronic component, so that the heat generated by the electronic component via the heat conduction surface 132 pass through the heat conduction block 130, the heat conduction side wall 131 and the inner side wall 112 of the base 110, and to the base 110. Preferably, an appropriate amount of heat conduction fluid which disposed in the gap 114 of dynamic heat conduction system 100 can optionally be provided, to increase the thermal conductivity between the heat conduction side wall 131 and the inner side wall 112 of the base 110. The heat conduction fluid can be a heat conduction paste known for one skilled in the art.

The groove 134 on the heat conduction side wall 131 can be used as a buffer space for a heat conduction fluid in the gap 114 when the present embodiment optionally provide the heat conduction fluid in the gap 114 of the dynamic heat conduction system 100. The groove 134 accommodates excessive heat conduction fluid when the heat conduction fluid in the gap 114 is in excess. The heat conduction fluid accommodating in the groove 134 provides to the gap 114 when the heat conduction fluid in the gap 114 is insufficient. In this way, the dynamic heat conduction system 100 of the present application can maintain an appropriate amount of heat conduction fluid in the gap 114 so that it can keep better heat conduction effects between the heat conduction side wall 131 and the inner side wall 112 of the base 110. Preferably, the dynamic heat conduction system of the present invention can optionally provide two or more grooves or a threaded groove on the heat conduction side wall to increase the cushioning effect for the heat conduction fluid. More preferably, the dynamic heat conduction system of the present invention can optionally not provide grooves on the heat conduction side wall to increase the contact area between the heat conduction side wall and the inner side wall of the base.

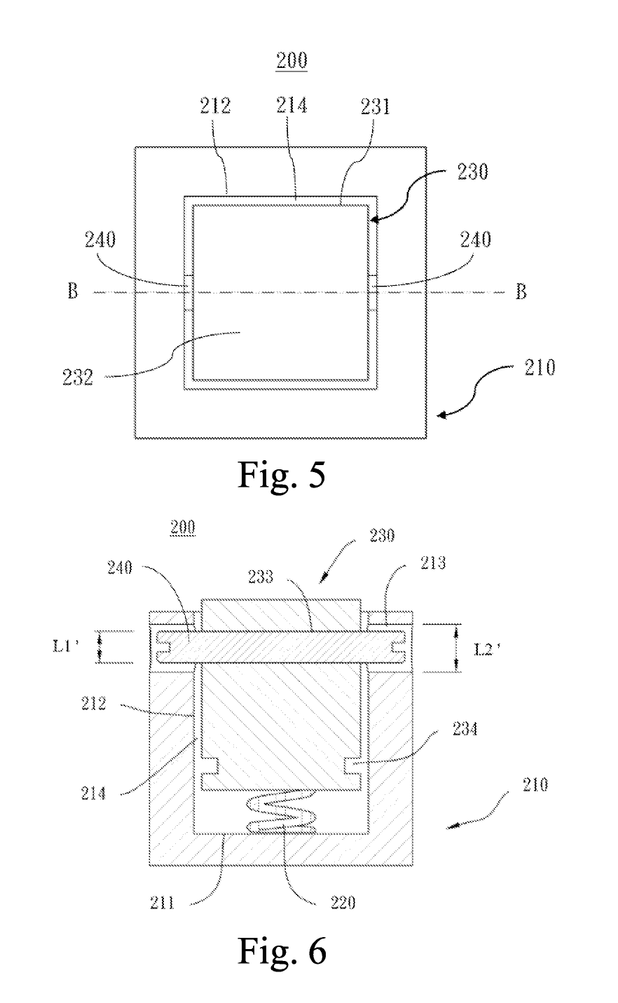

Then another embodiment of the present invention is described. Please refer to FIG. 5, which is a top view of a dynamic heat conduction system 200 according to the present invention. A heat conduction block 230 and a base 210 are shown as rectangle in the top view. The heat conduction block and the base of the dynamic heat conduction system in the top view can also be, for example, oval, circular, etc. or heat conduction surface areas or the base shedding surface areas which have different sizes to conform to the use of electronic components which having different shapes or contact surface areas. Preferably, resilient units of the dynamic heat conduction system can also have a different resilient unit area along the direction of a normal line to the heat conduction surface to conform to the use of electronic components which have different shapes or areas.

Please refer to FIG. 6, which is a sectional view drawn along line B-B as shown in FIG. 4. The heat conduction block 230 has a hole 233 penetrating the heat conduction block and forming two heat conduction block securing holes on the heat conduction side wall (Not shown). In the dynamic heat conduction system 200, a single securing unit 240 penetrates the heat conduction block 230 and be secured in the hole 233, and the both ends of securing unit 240 have at least one part be disposed in base securing holes 213 respectively. In addition, the securing unit 240 has a securing unit width L1′ along the direction of a normal line to a base surface 211; the base securing holes 213 has a base securing hole length L2′ along the direction of a normal line to the base surface 211. The condition of L2′>L1′ must be satisfied, so that at least one portion of the heat conduction block 230 is restricted within the base 210 by the securing unit 240 and the base securing holes 213 when the securing unit 240 and the heat conduction block 230 are movable in the direction of a normal line to the base surface 211. The dynamic heat conduction system of the present invention can optionally use two securing units disposing respectively on two heat conduction block securing holes which on the heat conduction side wall to reach the effect that at least one portion is restricted within the base.

The heat conduction surface 232 of the heat conduction block 230 can be closely contacted to a electronic component so that the heat generated by the electronic component via the heat conduction surface 232 passes through the heat conduction block 230, a heat conduction side wall 231 and a inner side wall 212 of the base 210 and transfers to the base 210. Preferably, the present invention can optionally provide an appropriate amount of heat conduction fluid which disposed in a gap 214 of dynamic heat conduction system 200 to increase the thermal conductivity between the heat conduction side wall 231 and the inner side wall 212 of the base 210. The heat conduction fluid can be a heat conduction paste known in the skill field.

The groove 234 on the heat conduction side wall 231 can be used as a buffer space for a heat conduction fluid in the gap 214 when the present embodiment optionally provide the heat conduction fluid in the gap 214 of the dynamic heat conduction system 200. The groove 234 accommodates excessive heat conduction fluid when the heat conduction fluid in the gap 214 is in excess. The heat conduction fluid accommodating in the groove 234 provides to the gap 214 when the heat conduction fluid in the gap 214 is insufficient. In this way, the dynamic heat conduction system 200 of the present application can maintain an appropriate amount of heat conduction fluid in the gap 214 so that it can keep better heat conduction effects between the heat conduction side wall 231 and the inner side wall 212 of the base 210. The dynamic heat conduction system of the present invention can optionally provide two or more grooves or a threaded groove on the heat conduction side wall to increase the cushioning effect for the heat conduction fluid. More preferably, the dynamic heat conduction system of the present invention can optionally not provide grooves on the heat conduction side wall, in order to increase the contact area between the heat conduction side wall and the inner side wall of the base.

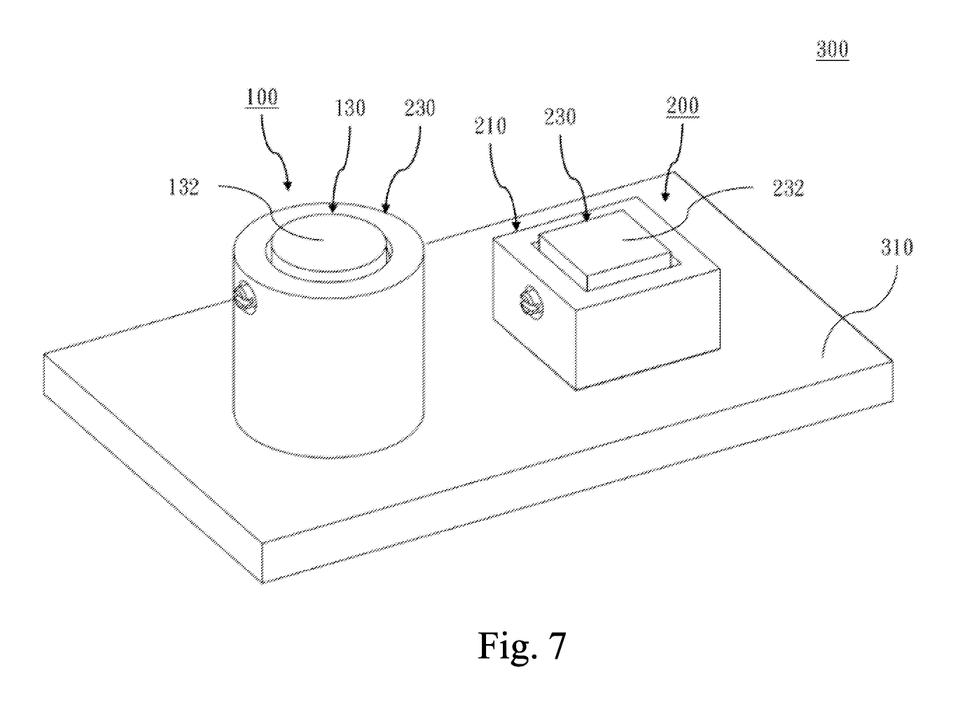

Please refer to FIG. 7, which is a perspective view of a dynamic heat conduction system 300 according to the present invention. The dynamic heat conduction system 100 as similar as shown in FIGS. 2, 3 & 4 and the dynamic heat conduction system 200 as shown in FIGS. 5 & 6 are disposed on the heat conduction board 310. The dynamic heat conduction systems 100, 200 are used a welded way of post processing nickel securing on the heat conduction board. Preferably, the present invention can also uses others, screws, for example, to secure the dynamic heat conduction system on the heat conduction board. In the present embodiment, by the heat conduction block 130, 230 of the dynamic heat conduction system 100, 200 can be moving along the direction of a normal line to the base. The dynamic heat conduction system 300 can be more closely contacting with two electronic components with different heights and avoid causing the condition of electronic components damaged which under pressure at the time of assembly or under external force after the assembly. In addition, the heat conduction surface 132 and 232 of the heat conduction block 130 and 230 respectively have shapes of circular and rectangular and different heat conduction surface areas, the base 110 and 120 have different shedding surface areas and the resilient unit respectively have different resilient unit areas so that the dynamic heat conduction system 300 can closely contact the electronic components having different contact surface areas and shapes at the same time. The bases have different heights, and the heat conduction blocks have different heights and the resilient unit have different heights and different resilient coefficients, so that the dynamic heat conduction system 300 can closely contact the electronic components having different heights at the same time. The present invention can be previously disposed a plurality of fillisters on the heat conduction board for receiving a plurality of dynamic heat conduction systems in the heat conduction board to increase the contact area of the base with the heat conduction board of the dynamic heat conduction system to achieving better heat conduction effects.

The present invention is not limited to providing two dynamic heat conduction systems on the heat conduction board. The one in the scope of the invention having the relevant art(s) can be learned that the invention can provide a single or a plurality of dissimilar dynamic heat conduction systems on the heat conduction board naturally by the contents of the invention disclosed. Preferably, the invention can provide the resilient units having different resilient coefficients or provide the dynamic heat conduction systems having different shapes, heights or areas which corresponding to electronic components with different heights, shapes or areas so that to achieve the purpose which having better heat conduction effects for a plurality of different electronic components at the same time, simplifying the complexity of manufacture and avoiding the electronic components damaged under external force in the assembly process or after the assembly.

After a detailed description of the preferred embodiments of the present invention, one skilled in the relevant art(s) can clearly understand that it can process various changing and modifying without departing from the spirit and scope of the invention. Therefore, the present invention should not be limited by any of the above-described exemplary embodiments in the specification.

What is claimed is:

1. A dynamic heat conduction system, comprising:
a base comprising a base surface and an inner side wall which defines at least two base securing holes having a base securing hole length along the direction of a normal line to the base surface;
a heat conduction block comprising a heat conduction side wall and a heat conduction surface, the heat conduction side wall being opposite to the inner side wall of the base and defining at least two heat conduction block securing holes at positions respectively corresponding to those of the base securing holes, the heat conduction block securing holes having a heat conduction block securing hole length along the direction of a normal line to the base surface of the base;
a resilient unit having one end being disposed on the base surface of the base and the other end being opposite to the base surface of the base and being engaged with the heat conduction block, so that the heat conduction block is disposed in the base and the heat conduction surface remains outside the base; and
at least one securing unit having at least one portion being secured to the heat conduction block securing holes respectively and at least another one of the other portions being disposed in the base securing holes respectively, the securing unit having a securing unit width along the direction of a normal line to the base surface of the base,
wherein the base securing hole length is greater than the securing unit width and the securing unit width is greater than or equal to the heat conduction block securing hole length, so that the heat conduction block is movable in the direction of a normal line to the heat conduction surface and at least one portion thereof is restricted within the base.

2. The dynamic heat conduction system of claim 1, wherein a gap accommodating a heat conduction fluid is defined between the heat conduction side wall and the inner side wall of the base.

3. The dynamic heat conduction system of claim 2, wherein the heat conduction block has at least one groove on the heat conduction side wall for accommodating the heat conduction fluid.

4. The dynamic heat conduction system of claim 1, wherein the heat conduction block has a hole penetrating the heat conduction block and forming the at least two heat conduction block securing holes on the heat conduction side wall.

5. A dynamic heat conduction system, comprising:
A heat conduction board covering a plurality of electronic components;
a plurality of bases disposed respectively on the heat conduction board at positions corresponding to the electronic components and respectively comprising a base surface and an inner side wall which defines at least two base securing holes having a base securing hole length along the direction of a normal line to the base surface;
a plurality of heat conduction blocks disposed respectively in the bases and respectively comprising a heat conduction side wall and a heat conduction surface, the heat conduction side walls respectively being opposite to the inner side wall of the bases and defining at least two heat conduction block securing holes at positions respectively corresponding to those of the base securing holes, the heat conduction block securing holes respectively having a heat conduction block securing hole length along the direction of a normal line to the base surface of the bases;
a plurality of resilient units disposed respectively in the bases and respectively having one end being disposed on the base surface of the bases and the other end respectively being opposite to the base surface of the bases and being engaged with the heat conduction blocks, so that the heat conduction blocks are disposed respectively in the bases and the heat conduction surfaces remain outside the bases; and
a plurality of securing units disposed respectively in the bases, respectively having at least one portion being secured to the heat conduction block securing holes and at least another portion being disposed in the base securing holes, and respectively having a securing unit width along the direction of a normal line to the base surface of the bases respectively,
wherein the base securing holes length are greater respectively than the securing units width and the securing units width are greater respectively than or equal to the heat conduction block securing holes length so that the heat conduction blocks are movable in the direction of a normal line to the heat conduction surface respectively and at least one portion thereof is restricted within the bases.

6. The dynamic heat conduction system of claim 5, wherein gaps respectively accommodating a heat conduction fluid is defined between the heat conduction side walls and the inner side wall of the bases.

7. The dynamic heat conduction system of claim 6, wherein the heat conduction blocks respectively have at least one groove on the heat conduction side walls for accommodating the heat conduction fluid.

8. The dynamic heat conduction system of claim 5, wherein the heat conduction blocks respectively have a hole penetrating the heat conduction blocks and forming the at least two heat conduction block securing holes on the heat conduction side walls respectively.

9. The dynamic heat conduction system of claim 5, wherein the bases have different heights respectively corresponding to that of each the electronic components.

10. The dynamic heat conduction system of claim 5, wherein the heat conduction blocks have different heights respectively corresponding to that of each the electronic components.

11. The dynamic heat conduction system of claim 5, wherein the resilient units have different heights or different resilient coefficients respectively corresponding to that of each the electronic components.

12. The dynamic heat conduction system of claim 5, wherein the bases have different shedding surface areas respectively corresponding to a contact surface area of each the electronic components and the heat conduction blocks have different heat conduction surface areas respectively corresponding to each the contact surfaces, and the resilient units have different resilient unit areas respectively corresponding to each the shedding surface areas.

13. The dynamic heat conduction system of claim 5, wherein the bases are welded with a post processing nickel and the heat conduction board.

14. The dynamic heat conduction system of claim 5, wherein the bases are secured on the heat conduction boards with screws.
